(19) United States
(12) Patent Application Publication
(10) Pub. No.: US 2026/0020141 A1
(43) Pub. Date: Jan. 15, 2026

(54) DRIVE PORTION FOR DISPLAY DEVICE, DISPLAY DEVICE, AND ELECTRONIC DEVICE INCLUDING THE SAME

(71) Applicant: Samsung Display Co., LTD., Yongin-si (KR)

(72) Inventors: JAEWOO KIM, Yongin-si (KR); Jeong-Young Kim, Yongin-si (KR); KIHAE SHIN, Yongin-si (KR)

(21) Appl. No.: 19/247,714

(22) Filed: Jun. 24, 2025

(30) Foreign Application Priority Data
Jul. 9, 2024 (KR) 10-2024-0090262

(51) Int. Cl. H05K 1/02; H05K 3/28

(52) U.S. Cl. CPC H05K 1/0218; H05K 1/0277; H05K 3/28; H05K 2201/10128

(57) ABSTRACT

A drive portion for a display device may include: a flexible circuit film; a circuit board connected to the flexible circuit film; a protective film surrounding the flexible circuit film and the circuit board; and a connection pattern positioned between the circuit board and the protective film, wherein a first thickness of the connection pattern is substantially equal to or greater than a sum of a second thickness of a protection layer positioned on a surface of the circuit board and a third thickness of an insulating layer positioned on a surface of the protective film.

This application claims priority to Korean Patent Application No. 10-2024-0090262, filed on Jul. 9, 2024, and all the benefits accruing therefrom under 35 U.S.C. § 119, the content of which in its entirety is herein incorporated by reference.

### BACKGROUND

### 1. Field

The present disclosure relates to a drive portion for a display device, a display device, and an electronic device including the display device.

### 2. Description of the Related Art

Display devices include liquid crystal displays (LCDs), plasma display panels (PDPs), organic light emitting diode (OLED) devices, field emission displays (FEDs), and electrophoretic display devices.

A display device may include a flexible circuit portion to transmit driving signals to a driving chip and a printed circuit board (PCB) connected to the flexible circuit portion, for displaying images on a display panel.

The drive portion of the display device may further include a cover film. The cover film may protect the driving chip, the flexible circuit portion, and the printed circuit board of the display device and may connect the ground of the display panel to the ground of the drive portion.

### SUMMARY

The present disclosure provides a drive portion for a display device and a display device including the drive portion that can stably connect the ground of the drive portion of the display device. The present disclosure further provides an electronic device including the display device.

In other embodiments, variations and modifications may be made within the technical scope of the disclosure.

According to an embodiment, a drive portion for a display device includes: a flexible circuit film; a circuit board connected to the flexible circuit film; a protective film surrounding the flexible circuit film and the circuit board; and a connection pattern positioned between the circuit board and the protective film. A first thickness of the connection pattern is substantially equal to or greater than a sum of a second thickness of a protection layer positioned on a surface of the circuit board and a third thickness of an insulating layer positioned on a surface of the protective film.

According to an embodiment, a display device includes: a display panel including a plurality of pixels; a flexible circuit film connected to the display panel; a circuit board connected to the flexible circuit film; a protective film surrounding the flexible circuit film and the circuit board; and a connection pattern positioned between the circuit board and the protective film. The first thickness of the connection pattern is substantially equal to or greater than a sum of a second thickness of a protection layer positioned on a surface of the circuit board and a third thickness of an insulating layer positioned on a surface of the protective film.

According to an embodiment, an electronic device includes a display device. The display device includes: a display panel including a plurality of pixels; a flexible circuit film connected to the display panel; a circuit board connected to the flexible circuit film; a protective film surrounding the flexible circuit film and the circuit board; and a connection pattern positioned between the circuit board and the protective film. The first thickness of the connection pattern is substantially equal to or greater than a sum of a second thickness of a protection layer positioned on a surface of the circuit board and a third thickness of an insulating layer positioned on a surface of the protective film.

The connection pattern may have conductivity.

The circuit board may include a ground pad portion, the protective film may include a ground layer, and the connection pattern may electrically connect the ground pad portion and the ground layer.

The connection pattern may include a first layer and a second layer positioned on the first layer. The first layer may have adhesiveness, and the first layer may adhere to the ground pad portion.

The thickness of the second layer may be greater than the thickness of the first layer.

The second layer may be in contact with the ground layer.

The protection layer of the circuit board may have a first contact hole at least partially overlapping with the ground pad portion, and the connection pattern may be positioned in the first contact hole.

The insulating layer of the protective film may have a second contact hole overlapping with a connection portion of the ground layer, and the connection pattern may contact the connection portion in the second contact hole.

The first contact hole and the second contact hole may overlap with each other.

The connection pattern may be spaced apart from a sidewall of the first contact hole by a first interval.

The first interval may be about 0.5 mm to about 1.5 mm.

The planar shape of the connection pattern may be substantially the same as the planar shape of the ground pad portion, and the planar area of the connection pattern may be smaller than the planar area of the ground pad portion.

The connection pattern may have a substantially rectangular planar shape.

According to embodiments, a drive portion for a display device and a display device including the drive portion that can stably connect the ground of the drive portion of the display device may be provided.

The effects of the embodiments can be variously extended beyond those described herein without departing from the scope of the disclosure.

### BRIEF DESCRIPTION OF THE DRAWINGS

FIG. 1 is a plan view of a display device according to an embodiment.

FIG. 2 is a cross-sectional view taken along line I-I′ of FIG. 1.

FIG. 3 is a cross-sectional view taken along line II-II′ of FIG. 1.

FIG. 4 is a plan view of a display device according to another embodiment.

FIG. 5 is a cross-sectional view taken along line I-I′ of FIG. 4.

FIG. 6 is a cross-sectional view taken along line II-II′ of FIG. 4.

FIG. 7 is a cross-sectional view taken along line III-III′ of FIG. 3.

FIG. 8 is a plan view illustrating a portion of a drive portion according to an embodiment.

FIG. 9 is a cross-sectional view illustrating a connection pattern portion according to an embodiment.

FIG. 10 is a cross-sectional view illustrating a connection pattern portion according to an embodiment.

FIG. 11 is a plan view illustrating a connection pattern portion according to an embodiment.

FIGS. 12, 14, and 16 are plan views illustrating a method of manufacturing a drive portion according to an embodiment.

FIGS. 13, 15, and 17 are cross-sectional views illustrating a method of manufacturing a drive portion according to an embodiment.

FIG. 18 is a block diagram of an electronic device according to an embodiment.

FIG. 19 is a schematic diagram of various electronic devices according to various embodiments.

### DETAILED DESCRIPTION

Various embodiments will be described in detail with reference to the accompanying drawings to enable one skilled in the art to implement them. The present disclosure may be implemented in various different forms and is not limited to the embodiments described herein.

Some elements are omitted from the drawings for clarity, and throughout the specification, like reference numerals refer to like elements.

The accompanying drawings facilitate understanding of the embodiments disclosed in this specification. The technical ideas disclosed in this specification include all modifications, equivalents, or substitutes within the spirit and scope of the present disclosure.

The size and thickness of each component illustrated in the drawings are illustrated arbitrarily for convenience of explanation. The present disclosure is not limited to what is illustrated. In the drawings, the thickness of layers and regions is exaggerated for clarity.

When a part is described as being “on” or “above” another part, it includes both cases where it is directly on the other part and where another part is between them. Conversely, when a part is described as being “directly on” another part, it means there is no other part between them. Being “on” or “above” a reference part means being located above or below the reference part, and does not necessarily mean being located in the direction opposite to gravity.

Throughout the specification, when one part “includes” a certain component, this does not exclude other components but means that other components can be further included unless specifically stated otherwise.

Throughout the specification, “in plan view” means viewing the target portion from above, and “in cross-sectional view” means viewing the cross-section of the target portion cut vertically from the side.

Throughout the specification, when components are described as “connected,” this may mean that two or more components are directly connected, indirectly connected through other components, physically connected, electrically connected, or integrated as one according to their position or function.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within +30%, 20%, 10%, 5% of the stated value, for example. The term “substantially,” as used herein, means approximately or actually.

The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as, for example, “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

Various embodiments and modifications will now be described in detail with reference to the drawings.

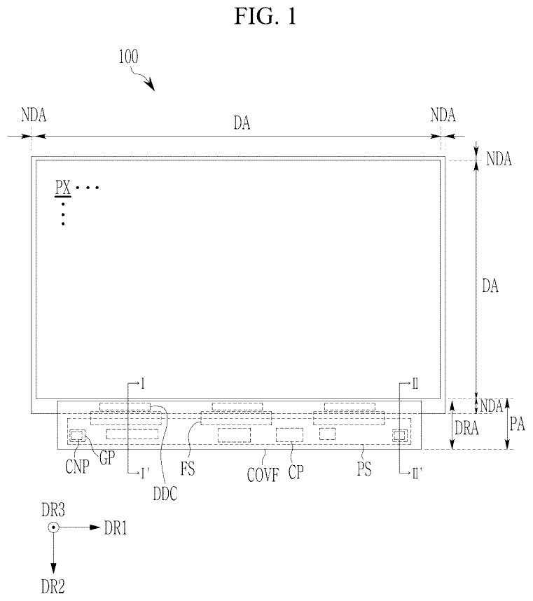

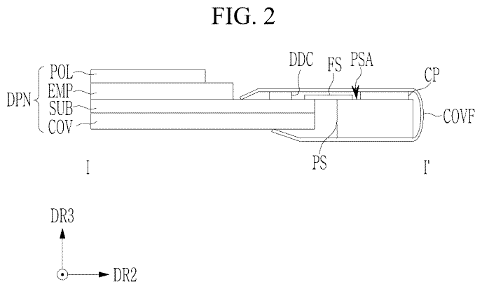

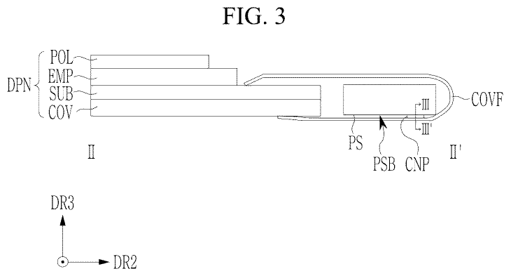

Referring to FIGS. 1 to 3, a display device 100 according to an embodiment will be described. FIG. 1 is a plan view of a display device according to an embodiment, FIG. 2 is a cross-sectional view taken along line I-I′ of FIG. 1, and FIG. 3 is a cross-sectional view taken along line II-II′ of FIG. 1.

Referring to FIGS. 1 to 3, the display device 100 according to this embodiment may include a display panel DPN having a display area DA where a plurality of pixels PX are arranged along different first direction DR1 and second direction DR2 and display images, and a non-display area NDA surrounding the display area DA.

A drive area DRA including a plurality of driving chips DDC, a flexible circuit film FS connected to the display panel DPN, and a circuit board PS physically and electrically connected to the flexible circuit film FS may be positioned at a part of the outer periphery of the non-display area NDA of the display panel DPN.

The drive area DRA may be positioned below the non-display area NDA of the display panel DPN along the second direction DR2, but is not limited thereto.

A plurality of driving chips DDC may be positioned at a part of the outer periphery of the non-display area NDA of the display panel DPN. The plurality of driving chips DDC may include Display Driver IC (DDI) chips, timing controllers (T-CON), graphic random access memory (GRAM), power generating circuits, or the like.

The plurality of driving chips DDC may transmit and receive driving signals through the flexible circuit film FS connected to the circuit board PS.

The plurality of driving chips DDC may be positioned directly on the substrate SUB and may be connected to the substrate SUB through a film substrate.

The display panel DPN may include a substrate SUB, a plurality of emission portions EMP positioned on the substrate SUB, a polarization portion POL positioned on the plurality of emission portions EMP of the substrate SUB, and a protection portion COV positioned below the substrate SUB.

A plurality of electronic components CP may be arranged on a first surface PSA of the circuit board PS.

At least one ground pad portion GP may be positioned on a second surface PSB of the circuit board PS. The ground pad portion GP may be connected to the ground wiring of the circuit board PS.

A cover film COVF may be positioned in the peripheral area PA. The cover film COVF may surround the plurality of driving chips DDC, the flexible circuit film FS, and the circuit board PS from the front to the back of the display panel DPN.

The cover film COVF may protect and fix the plurality of driving chips DDC, the flexible circuit film FS, and the circuit board PS of the drive area DRA, shield radio frequency (RF) noise between the drive area DRA and the outside. The cover film COVF may connect the ground wiring of the circuit board PS and the ground wiring of the display panel DPN to provide stable ground or provide a path for static electricity. The cover film COVF may also be referred to herein as a protective film.

A connection pattern portion CNP may be positioned between the ground pad portion GP of the circuit board PS and the cover film COVF.

The connection pattern portion CNP facilitates the electrical connection between the ground pad portion GP of the circuit board PS and the cover film COVF.

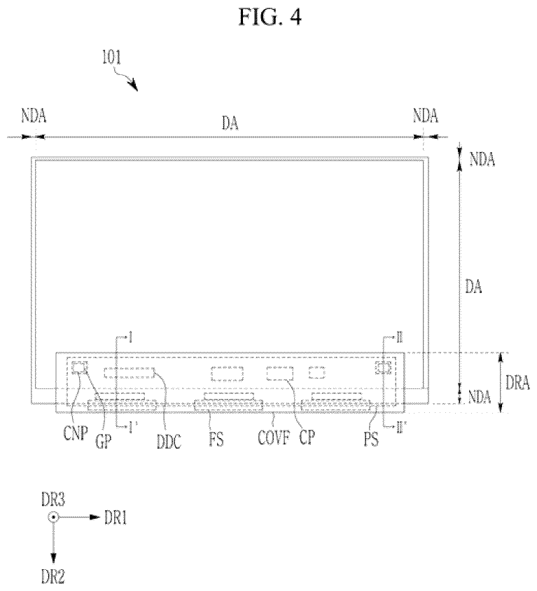

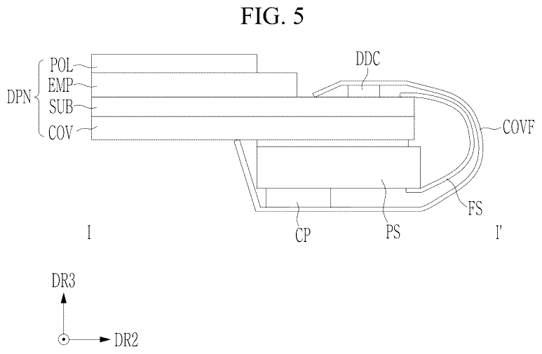

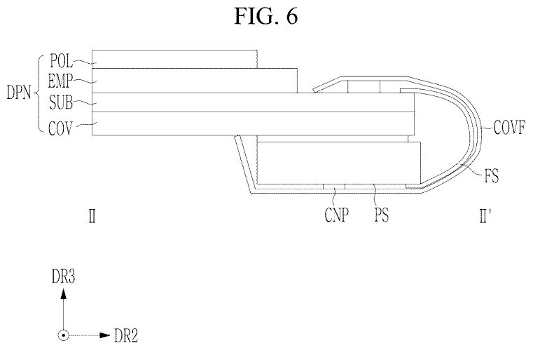

Referring to FIGS. 4 to 6, a display device 101 according to another embodiment will be described. FIG. 4 is a plan view of a display device according to another embodiment, FIG. 5 is a cross-sectional view taken along line I-I′ of FIG. 4, and FIG. 6 is a cross-sectional view taken along line II-II′ of FIG. 4.

Referring to FIGS. 4 to 6, the display device 101 according to this embodiment is similar to the display device 100 described with reference to FIGS. 1 to 3. Detailed descriptions of identical components are omitted.

Referring to FIGS. 4 to 6, the display device 101 according to this embodiment may include a display panel DPN having a display area DA where a plurality of pixels PX are positioned and display images, and a non-display area NDA surrounding the display area DA.

The drive area DRA positioned at a part of the outer periphery of the non-display area NDA of the display panel DPN may include a plurality of driving chips DDC, a flexible circuit film FS connected to the display panel DPN, and a circuit board PS physically and electrically connected to the flexible circuit film FS.

A plurality of driving chips DDC may be positioned at a part of the outer periphery of the non-display area NDA of the display panel DPN. The plurality of driving chips DDC may transmit and receive driving signals through the flexible circuit film FS connected to the circuit board PS.

The flexible circuit film FS may be connected to the substrate SUB, and from the portion connected to the substrate SUB, a part of the flexible circuit film FS may be bent toward the back of the display panel DPN and positioned on the back of the display panel DPN.

The flexible circuit film FS may be bent such that a part of the flexible circuit film FS is positioned on the back of the display panel DPN, and the bent portion of the flexible circuit film FS is connected to the circuit board PS. This reduces the width of the peripheral area PA measured along the second direction DR2 compared to an arrangement where the flexible circuit film FS is not bent and the display panel DPN, flexible circuit film FS, and circuit board PS are arranged in a line along the second direction DR2.

A plurality of electronic components CP may be arranged on the circuit board PS.

The circuit board PS may include at least one ground pad portion GP. The ground pad portion GP may be connected to the ground wiring of the circuit board PS.

A cover film COVF may be positioned in the peripheral area PA. The cover film COVF may surround the plurality of driving chips DDC, the flexible circuit film FS, and the circuit board PS from the front to the back of the display panel DPN.

The cover film COVF may protect and fix the plurality of driving chips DDC, the flexible circuit film FS, and the circuit board PS of the drive area DRA, shield RF noise between the drive area DRA and the outside. The cover film COVF may connect the ground wiring of the circuit board PS and the ground wiring of the display panel DPN to provide stable ground or provide a path for static electricity.

A connection pattern portion CNP may be positioned between the ground pad portion GP of the circuit board PS and the cover film COVF.

The connection pattern portion CNP facilitates the electrical connection between the ground pad portion GP of the circuit board PS and the cover film COVF. Embodiments of the present disclosure may refer to multiple connection pattern portions CNP as an overall connection pattern. In some aspects, the terms connection pattern portion and connection pattern may be used interchangeably herein.

Many features of the display device 100 according to the previously described embodiment are applicable to this embodiment.

In the display devices 100, 101 according to the previously described embodiments, although the width of the display panel DPN parallel to the first direction DR1 is illustrated to be wider than the width parallel to the second direction DR2, the embodiments are not limited thereto. In some aspects, in the display devices 100, 101 according to the previously described embodiments, although the circuit board PS is illustrated to be positioned below the display panel DPN along the second direction DR2, the embodiments are not limited thereto. In some aspects, in the display devices 100, 101 according to the previously described embodiments, although the flexible circuit film FS and the connection portion GRLC are illustrated to be one, the embodiments are not limited thereto. In some aspects, in the display devices 100, 101 according to the previously described embodiments, although the plurality of driving chips DDC are illustrated to be positioned on the substrate SUB, the embodiments are not limited thereto, and the plurality of driving chips DDC may be positioned on the flexible circuit film FS or may be positioned on an additional circuit film.

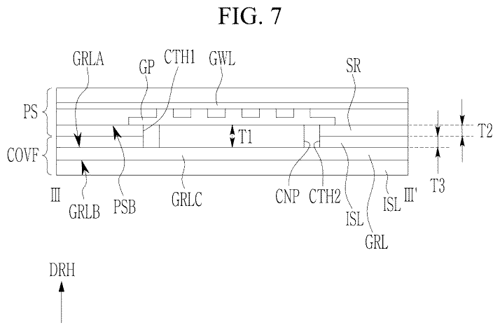

Referring to FIG. 7, the electrical connection between the circuit board PS and the cover film COVF will be described in more detail. FIG. 7 is an enlarged cross-sectional view of a part of the drive portion of the display device according to an embodiment. FIG. 7 is a cross-sectional view taken along line III-III′ of FIG. 3.

Referring to FIG. 7, along the height direction DRH perpendicular to the first surface PSA and second surface PSB of the circuit board PS, protection layers SR may be positioned on the surfaces of the first surface PSA and second surface PSB of the circuit board PS.

The protection layers SR may protect the circuit board PS and may include an insulating layer. The protection layer SR may be a solder resist, but the embodiments are not limited thereto.

The protection layer SR positioned on the second surface PSB of the circuit board PS (the protection layer SR of the circuit board PS) may have first contact holes CTH1 overlapping with ground pad portions GP connected to the ground wiring GWL. For example, the first contact holes CTH1 may partially overlap with ground pad portions GP.

The cover film COVF may include a ground layer GRL and insulating layers ISL positioned on both surfaces GRLA, GRLB of the ground layer GRL.

Along the height direction DRH, the insulating layers ISL may overlap with the ground layer GRL, and the insulating layers ISL may cover and protect the first surface GRLA and second surface GRLB of the ground layer GRL which face each other. The insulating layers ISL may include insulating material.

The insulating layer ISL positioned on the first surface GRLA of the cover film COVF (the insulating layer ISL of the cover film COVF/protective film) may have second contact holes CTH2 overlapping with portions of the ground layer GRL. The connection portions GRLC of the ground layer GRL may be exposed by the second contact holes CTH2, and the connection portions GRLC of the ground layer GRL overlapping with the second contact holes CTH2 may be electrically connected to the ground pad portions GP overlapping with the first contact holes CTH1 of the protection layer SR positioned on the second surface PSB of the circuit board PS.

Along the height direction DRH, the first contact holes CTH1 of the protection layer SR positioned on the second surface PSB of the circuit board PS may overlap with the second contact holes CTH2 of the insulating layer ISL positioned on the first surface GRLA of the cover film COVF.

Connection pattern portions CNP may be positioned in the first contact holes CTH1 and the second contact holes CTH2.

The connection pattern portions CNP may have conductivity and may have at least partial elasticity.

The connection pattern portions CNP may be positioned between the ground pad portions GP overlapping with the first contact holes CTH1 of the circuit board PS and the connection portions GRLC of the ground layer GRL overlapping with the second contact holes CTH2. This electrically connects the ground pad portions GP and the connection portions GRLC of the ground layer GRL to each other, such that the ground wiring GWL of the circuit board PS and the ground layer GRL of the cover film COVF are connected to each other to provide ground to the circuit board PS.

The first thickness T1 of the connection pattern portions CNP may be substantially equal to or greater than the sum of the second thickness T2 of the protection layer SR positioned on the surface (e.g., the second surface PSB) of the circuit board PS and the third thickness T3 of the insulating layer ISL positioned on the surface (e.g., the first surface GRLA) of the cover film COVF.

Because of the protection layer SR positioned on the surface of the circuit board PS and the insulating layer ISL positioned on the surface of the cover film COVF, the ground pad portions GP and the connection portions GRLC of the ground layer GRL may be spaced apart along the height direction DRH by the sum of the thicknesses of the protection layer SR and the insulating layer ISL. Therefore, without connection pattern portions CNP between the ground wiring GWL of the circuit board PS and the ground layer GRL of the cover film COVF, the electrical connection between the ground pad portion GP of the circuit board PS and the ground layer GRL of the cover film COVF is easily broken.

According to the embodiment, by having connection pattern portions CNP with a first thickness T1 that is substantially equal to or greater than the sum of the second thickness T2 of the protection layer SR positioned on the surface of the circuit board PS and the third thickness T3 of the insulating layer ISL positioned on the surface of the cover film COVF positioned between the ground pad portion GP of the circuit board PS and the ground layer GRL of the cover film COVF, the ground pad portion GP of the circuit board PS and the ground layer GRL of the cover film COVF spaced apart from each other can be electrically connected stably.

According to the embodiment, by including connection pattern portions CNP which are positioned between and can connect the ground pad portions GP overlapping with the first contact holes CTH1 of the circuit board PS and the connection portions GRLC of the ground layer GRL overlapping with the second contact holes CTH2 of the cover film COVF, the ground wiring GWL of the circuit board PS and the ground layer GRL of the cover film COVF can be stably connected to each other.

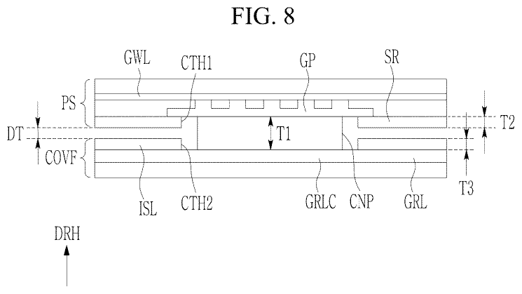

Referring to FIG. 8, the thickness of the connection pattern CNP portions according to an embodiment will be described. FIG. 8 is a plan view illustrating a portion of a drive portion according to an embodiment.

As described herein, the connection pattern portions CNP may have conductivity and may have at least partial elasticity.

According to the embodiment, the first thickness T1 of the connection pattern portions CNP may be greater than the sum of the second thickness T2 of the protection layer SR positioned on the surface of the circuit board PS and the third thickness T3 of the insulating layer ISL positioned on the surface of the cover film COVF.

As illustrated in FIG. 8, even in cases where the circuit board PS and the cover film COVF do not contact each other and are spaced apart by a first interval DT, by having connection pattern portions CNP with a first thickness T1 greater than the sum of the second thickness T2 of the protection layer SR positioned on the surface of the circuit board PS and the third thickness T3 of the insulating layer ISL positioned on the surface of the cover film COVF positioned between the ground pad portion GP of the circuit board PS and the ground layer GRL of the cover film COVF, the ground wiring GWL of the circuit board PS and the ground layer GRL of the cover film COVF can be electrically connected stably.

According to the embodiment, the drive portion of the display device includes the connection pattern portions CNP located between the ground pad portions GP which overlap with the first contact holes CTH1 in the circuit board PS and the connection portions GRLC of the ground layer GRL which overlap with the second contact holes CTH2 in the cover film COVF such that the ground pad portions GP and the connection portions GRLC may be connected through the connection pattern portions CNP. Accordingly, the ground wiring GWL of the circuit board PS and the ground layer GRL of the cover film COVF can be stably connected to each other.

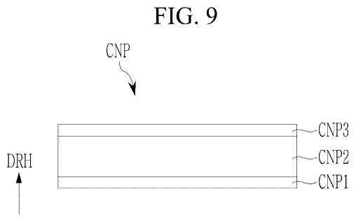

Referring to FIG. 9, the structure of the connection pattern portions CNP according to an embodiment will be described. FIG. 9 is a cross-sectional view illustrating a connection pattern portion according to an embodiment.

Referring to FIG. 9, the connection pattern portions CNP according to the embodiment may include a first layer CNP1, a second layer CNP2, and a third layer CNP3 stacked in order.

The first layer CNP1 of the connection pattern portion CNP may have adhesiveness and conductivity. The first layer CNP1 of the connection pattern portion CNP may contact the ground pad portions GP overlapping with the first contact holes CTH1 of the circuit board PS.

The third layer CNP3 of the connection pattern portion CNP may contact the connection portions GRLC of the ground layer GRL overlapping with the second contact holes CTH2 of the cover film COVF. The third layer CNP3 of the connection pattern portion CNP may have conductivity and may or may not have adhesiveness.

The second layer CNP2 of the connection pattern portion CNP may be thicker than the first layer CNP1 and the third layer CNP3 and may have conductivity, for example, may include a conductive wire fiber layer, but the embodiments are not limited thereto.

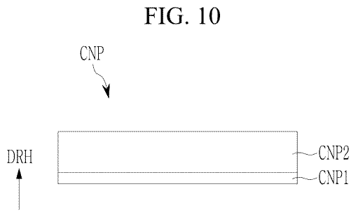

Referring to FIG. 10, the structure of the connection pattern portions CNP according to an embodiment will be described. FIG. 10 is a cross-sectional view illustrating a connection pattern portion according to an embodiment.

Referring to FIG. 10, the connection pattern portions CNP according to the embodiment may include a first layer CNP1 and a second layer CNP2 overlapping each other.

The first layer CNP1 of the connection pattern portion CNP may have adhesiveness and conductivity. The first layer CNP1 of the connection pattern portion CNP may contact the ground pad portions GP overlapping with the first contact holes CTH1 of the circuit board PS.

The second layer CNP2 of the connection pattern portion CNP may contact the connection portions GRLC of the ground layer GRL overlapping with the second contact holes CTH2 of the cover film COVF.

The second layer CNP2 of the connection pattern portion CNP may be thicker than the first layer CNP1 and may have conductivity, for example, may include a conductive wire fiber layer, but the embodiments are not limited thereto.

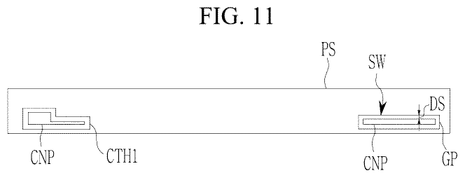

Referring to FIG. 11, the planar shape of the connection pattern portions CNP according to an embodiment will be described. FIG. 11 is a plan view illustrating a connection pattern portion according to an embodiment.

Referring to FIG. 11, the connection pattern portions CNP according to the embodiment may have a planar shape similar to the planar shape of the first contact holes CTH1 overlapping with the ground pad portions GP of the circuit board PS. In other embodiments, the connection pattern portions CNP may have a rectangular planar shape and may be attached in the first contact holes CTH1 regardless of the planar shape of the first contact holes CTH1 overlapping with the ground pad portions GP.

The planar area of the connection pattern portions CNP may be smaller than the planar area of the first contact holes CTH1 and may be smaller than the planar area of the ground pad portions GP overlapping with the first contact holes CTH1.

The connection pattern portions CNP may be completely contained in the first contact holes CTH1 and may be spaced apart from the sidewalls SW of the first contact holes CTH1 by a predetermined interval DS. For example, the interval DS between the edges of the connection pattern portions CNP and the sidewalls SW of the first contact holes CTH1 may be about 0.5 mm to about 1.5 mm, and more specifically, the interval DS between the edges of the connection pattern portions CNP and the sidewalls SW of the first contact holes CTH1 may be about 0.8 mm to about 1.2 mm.

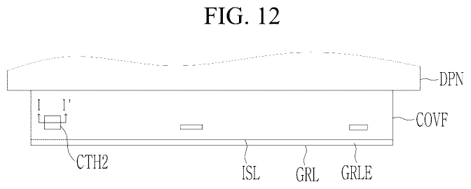

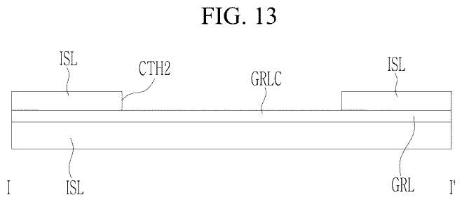

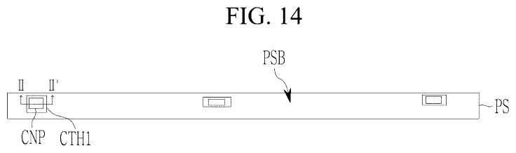

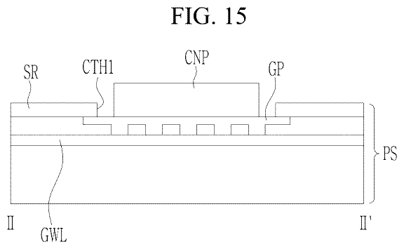

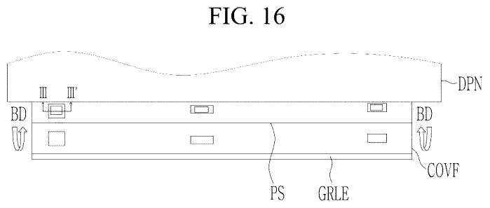

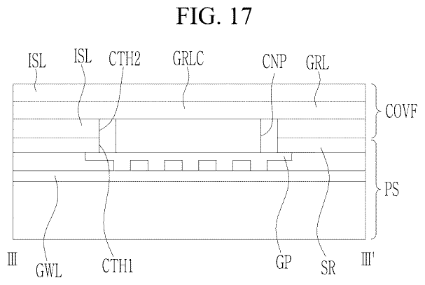

Referring to FIGS. 1 to 11 along with FIGS. 12 to 17, a method of manufacturing a drive portion according to an embodiment will be described. FIGS. 12, 14, and 16 are plan views illustrating a method of manufacturing a drive portion according to an embodiment, and FIGS. 13, 15, and 17 are cross-sectional views illustrating a method of manufacturing a drive portion according to an embodiment. FIG. 13 is a cross-sectional view taken along line I-I′ of FIG. 12, FIG. 15 is a cross-sectional view taken along line II-II′ of FIG. 14, and FIG. 17 is a cross-sectional view taken along line III-III′ of FIG. 16.

Referring to FIGS. 1 to 11 along with FIGS. 12 and 13, the insulating layer ISL positioned on the back of the cover film COVF attached to the front of the display panel DPN may have second contact holes CTH2 overlapping with the connection portions GRLC of the ground layer GRL.

The end portion GRLE of the ground layer GRL of the cover film COVF may not be covered by the insulating layer ISL and may be exposed.

Referring to FIGS. 1 to 11 along with FIGS. 14 and 15, the protection layer SR positioned on the second surface PSB, which is the back surface of the circuit board PS, may have first contact holes CTH1 overlapping with the ground pad portions GP connected to the ground wiring GWL.

Connection pattern portions CNP may be positioned in the first contact holes CTH1 overlapping with the ground pad portions GP.

As described herein, the first layer CNP1 of the connection pattern portions CNP may have adhesiveness. Therefore, the connection pattern portions CNP may adhere to the ground pad portions GP overlapping with the first contact holes CTH1.

Referring to FIGS. 1 to 11 along with FIGS. 16 and 17, in cases where the circuit board PS connected to the flexible circuit film FS is positioned on the cover film COVF and the end portion of the cover film COVF is bent BD toward the back of the display panel DPN and pressure is applied, the connection portions GRLC of the ground layer GRL overlapping with the second contact holes CTH2 of the cover film COVF may be electrically connected to the ground pad portions GP overlapping with the first contact holes CTH1 of the protection layer SR positioned on the second surface PSB of the circuit board PS through the connection pattern portions CNP.

The end portion GRLE of the ground layer GRL of the cover film COVF which is not covered by the insulating layer ISL and is exposed may be electrically connected to the ground wiring of the display panel DPN.

Accordingly, for example, the ground wiring GWL of the circuit board PS and the ground wiring of the display panel DPN can be connected to each other through the cover film COVF. Through the connection, the ground of the display device can be stably set, and in cases where static electricity is generated in the display panel DPN, a discharge path for the static electricity can be provided to prevent degradation of the display device performance due to static electricity.

According to the embodiment, the connection pattern portions CNP have a first thickness T1 which is substantially equal to or greater than a sum of a second thickness T2 of the protection layer SR on the surface of the circuit board PS and a third thickness T3 of the insulating layer ISL on the surface of the cover film COVF, wherein the connection pattern portions CNP are positioned between the ground pad portion GP of the circuit board PS and the ground layer GRL of the cover film COVF, such that the ground pad portion GP of the circuit board PS and the ground layer GRL of the cover film COVF can be stably and electrically connected to each other while being spatially separated.

According to the embodiment, the drive portion of the display device includes the connection pattern portions CNP located between the ground pad portions GP which overlap with the first contact holes CTH1 in the circuit board PS and the connection portions GRLC of the ground layer GRL which overlap with the second contact holes CTH2 in the cover film COVF such that the ground pad portions GP and the connection portions GRLC may be connected through the connection pattern portions CNP. Accordingly, the ground wiring GWL of the circuit board PS and the ground layer GRL of the cover film COVF can be stably connected to each other.

The display device according to the embodiments can be applied to various electronic devices. An electronic device according to an embodiment includes the display device described herein, and may further include modules or devices having other additional functions besides the display device.

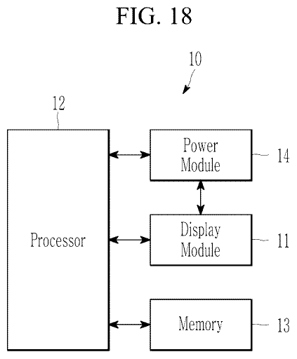

FIG. 18 is a block diagram of an electronic device according to an embodiment. Referring to FIG. 18, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. Data information for the operation of the processor 12 or the display module 11 may be stored in the memory 13. In an example in which the processor 12 executes an application stored in the memory 13, image data signals and input control signals are transmitted to the display module 11, and the display module 11 can process the provided signals and output image information through the display screen.

The power module 14 may include a power supply module such as, for example, a power adapter or battery device and a power conversion module which converts power supplied by the power supply module to generate power for the operation of the electronic device 10.

At least one of components of the electronic device 10 described herein may be included in the display device according to the embodiments described herein. In other embodiments, some of the individual modules which are functionally included in one module may be included in the display device, and other portions may be provided separately from the display device. For example, the display device may include the display module 11, and the processor 12, memory 13, and power module 14 may be provided in the form of other devices in the electronic device 10 which are not the display device.

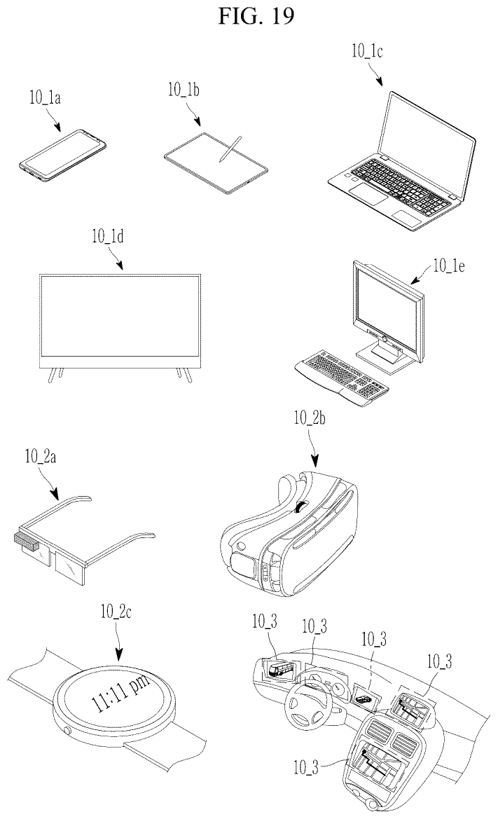

FIG. 19 is a schematic diagram of various electronic devices according to various embodiments.

Referring to FIG. 19, various electronic devices to which the display device according to the embodiments can be applied may include not only image display electronic devices such as, for example, smartphones 10_1a, tablet personal computers (PCs) 10_1b, laptops 10_1c, TVs 10_1d, and desktop monitors 10_1e, but also wearable electronic devices including display modules such as, for example, smart glasses 10_2a, head-mounted displays 10_2b, and smart watches 10_2c, and vehicle electronic devices 10_3 including display modules such as, for example, car instrument panels, center fascias, dashboards, CID (Center Information Display), and room mirror displays.

While the present disclosure has been described with reference to embodiments, it will be apparent to those of ordinary skill in the art that various changes and modifications may be made without departing from the spirit and scope of the present disclosure as defined by the following claims and their equivalents.

What is claimed is:

1. A drive portion for a display device, comprising:
a flexible circuit film;
a circuit board connected to the flexible circuit film;
a protective film surrounding the flexible circuit film and the circuit board; and
a connection pattern positioned between the circuit board and the protective film,
wherein a first thickness of the connection pattern is substantially equal to or greater than a sum of a second thickness of a protection layer positioned on a surface of the circuit board and a third thickness of an insulating layer positioned on a surface of the protective film.

2. The drive portion of claim 1, wherein the connection pattern has conductivity.

3. The drive portion of claim 2, wherein:
the circuit board comprises a ground pad portion,
the protective film comprises a ground layer, and
the connection pattern electrically connects the ground pad portion and the ground layer.

4. The drive portion of claim 3, wherein:
the connection pattern comprises a first layer and a second layer positioned on the first layer,
the first layer has adhesiveness, and
the first layer adheres to the ground pad portion.

5. The drive portion of claim 4, wherein:
a thickness of the second layer is greater than a thickness of the first layer; and
the second layer is in contact with the ground layer.

6. The drive portion of claim 4, wherein:
the connection pattern further comprises a third layer positioned on the second layer, and
the third layer is in contact with the ground layer.

7. The drive portion of claim 3, wherein:
the protection layer of the circuit board has a first contact hole at least partially overlapping with the ground pad portion, and
the connection pattern is positioned in the first contact hole.

8. The drive portion of claim 7, wherein:
the insulating layer of the protective film has a second contact hole overlapping with a connection portion of the ground layer, and
the connection pattern contacts the connection portion in the second contact hole.

9. The drive portion of claim 8, wherein the first contact hole and the second contact hole overlap with each other.

10. The drive portion of claim 7, wherein:
the connection pattern is spaced apart from a sidewall of the first contact hole by a first interval; and
the first interval is about 0.5 mm to about 1.5 mm.

11. The drive portion of claim 3, wherein:
a planar shape of the connection pattern is substantially the same as a planar shape of the ground pad portion, and
a planar area of the connection pattern is smaller than a planar area of the ground pad portion.

12. The drive portion of claim 3, wherein the connection pattern has a substantially rectangular planar shape.

13. A display device, comprising:
a display panel comprising a plurality of pixels;
a flexible circuit film connected to the display panel;
a circuit board connected to the flexible circuit film;
a protective film surrounding the flexible circuit film and the circuit board; and
a connection pattern positioned between the circuit board and the protective film,
wherein a first thickness of the connection pattern is substantially equal to or greater than a sum of a second thickness of a protection layer positioned on a surface of the circuit board and a third thickness of an insulating layer positioned on a surface of the protective film.

14. The display device of claim 13, wherein:
the circuit board comprises a ground pad portion,
the protective film comprises a ground layer,
the connection pattern has conductivity, and
the connection pattern electrically connects the ground pad portion and the ground layer.

15. The display device of claim 14, wherein:
the connection pattern comprises a first layer and a second layer positioned on the first layer,
the first layer has adhesiveness,
a thickness of the second layer is greater than a thickness of the first layer, and
the first layer adheres to the ground pad portion.

16. The display device of claim 15, wherein:
the connection pattern further comprises a third layer positioned on the second layer, and
the third layer is in contact with the ground layer.

17. The display device of claim 14, wherein:
the protection layer of the circuit board has a first contact hole at least partially overlapping with the ground pad portion,
the insulating layer of the protective film has a second contact hole overlapping with a connection portion of the ground layer, and
the connection pattern is positioned in the first contact hole and the second contact hole.

18. The display device of claim 17, wherein:
the connection pattern is spaced apart from a sidewall of the first contact hole by a first interval, and
the first interval is about 0.5 mm to about 1.5 mm.

19. An electronic device comprising a display device,
wherein the display device comprises:
a display panel comprising a plurality of pixels;
a flexible circuit film connected to the display panel;
a circuit board connected to the flexible circuit film;
a protective film surrounding the flexible circuit film and the circuit board; and
a connection pattern positioned between the circuit board and the protective film,
wherein a first thickness of the connection pattern is substantially equal to or greater than a sum of a second thickness of a protection layer positioned on a surface of the circuit board and a third thickness of an insulating layer positioned on a surface of the protective film.

20. The electronic device of claim 19, wherein:
the circuit board comprises a ground pad portion,
the protective film comprises a ground layer,
the connection pattern has conductivity, and
the connection pattern electrically connects the ground pad portion and the ground layer.
